(19) United States
(12) Patent Application Publication
(10) Pub. No.: US 2006/0003603 A1
(43) Pub. Date: Jan. 5, 2006

(54) Method and apparatus for processing

(75) Inventor: Yusuke Fukuchi, Tokyo (JP)

Correspondence Address: FITZPATRICK CELLA HARPER & SCINTO, 30 ROCKEFELLER PLAZA, NEW YORK, NY, 10112, US

(73) Assignee: CANNON KABUSHIKI KAISHA, Tokyo (JP)

(21) Appl. No.: 11/165,505

(22) Filed: Jun. 24, 2005

(30) Foreign Application Priority Data
Jun. 30, 2004 (JP) 2004-194233

(51) Int. Cl. H01L 21/469; C23C 16/00

(52) U.S. Cl. 438/787; 118/715; 438/788

(57) ABSTRACT

A method for forming an insulating film low in defects, in high throughput and with high reliability includes a first step of oxidizing an article employing a plasma having oxidizing species including ions to form an oxide film having a desired film thickness, and a second step of controlling an amount of the ions in the plasma at a surface of the article to be processed employing neutral radicals.

### BACKGROUND OF THE INVENTION

1. Field of the Invention

The present invention relates to a processing method, and particularly a plasma processing method. The present invention is suitable for, for example, plasma processing for forming an insulating film of a semiconductor device.

2. Description of the Related Art

Conventionally, a silicon dioxide film used as an insulating film of an MOS (Metal-Oxide Semiconductor) type semiconductor device has high band gap energy and excellent interfacial characteristics, and has supported semiconductor device characteristics which require high reliability. As a method for forming the silicon dioxide film used as a gate insulating film of an MOS transistor, a thermal oxidation method has widely been used. The thermal oxidation method involves heating a silicon substrate at a high temperature of about 1,000° C., and oxidizing the substrate under an oxidation atmosphere of dry oxygen, water vapor or the like.

However, as VLSI (Very Large Scale Integration) has been highly integrated and the insulating film has been thinned, an oxide film formed by the conventional thermal oxidation method decreases a dielectric breakdown voltage and significantly increases a leakage current as a direct tunnel current flows. Thus, it has become difficult to ensure adequate performance as an insulating film. In addition, there is also a problem that the thermal oxidation method imposes a high thermal load on a substrate, thereby causing the re-diffusion of impurities already formed in the substrate.

Therefore, a method of using active species including ions and neutral radicals for an oxidation reaction is now receiving attention. This method generally forms fewer lattice defects in a film during oxidation of the silicon substrate than in the case of a dry thermal oxide film. Further, in this method the oxidation progresses even at a low temperature.

In order to generate active species there are various methods such as irradiating with UV light having a specific wavelength under an oxygen atmosphere, applying a high-frequency field thereby turning an oxidative gas into plasma to cause dissociation, and the like.

However, since it is difficult to generate a large amount of active species by irradiating with UV light, this method has the drawbacks of being slow in oxidation rate and being low in throughput. In contrast, when generating active specifies by applying a high frequency field to form a plasma, a large amount of active species can be generated relatively easy and a high rate of oxidation can be obtained. However, when a plasma is introduced, then, in addition to neutral radical species, ions are also generated as the active species, simultaneously. The ions are accelerated to a high speed by the sheath potential which is formed on the substrate, and are implanted in the substrate. Consequently this phenomenon causes damage to an atomic bond in the substrate, and causes defects providing a fixed charge such as dangling bonds. On the other hand, in a case of down flow oxidation which uses remote plasma or the like, an amount of ion component arriving at the surface of the substrate is relatively low. This causes a problem in that, as in the case of UV photo-oxidation, the neutral radical species arriving at the substrate are also reduced in quality and thus the rate of the oxidation is reduced and productivity is low.

As described above, in the conventional oxidation method using an active species, it is difficult to maintain a uniform concentration of neutral radicals at the surface of the substrate while also preventing the adverse effects of ion implantation at the same time. As a result, there is a reduction in throughput. Therefore, the conventional oxidation method has not supplanted the thermal oxidation method.

### SUMMARY OF THE INVENTION

An aspect of the present invention is to overcome the above-described drawbacks.

In one aspect of the present invention, a processing method is provided forming an oxide film which includes a first step of oxidizing an article employing a plasma comprising oxidizing species including ions to form the oxide film having a desired film thickness, and a second step of controlling an amount of the ions in the plasma at the surface of the article such that the article is processed by neutral radical species. The desired film thickness is preferably in a range of 30 to 200 Å.

Other features and advantages of the present invention will become apparent to those skilled in the art upon reading of the following detailed description of embodiments thereof when taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic cross-sectional view showing a microwave plasma processing apparatus according to a first embodiment of the present invention.

FIG. 2 is a diagram showing the relation between the pressure and the distance of a plasma density in utilizing a microwave plasma processing apparatus shown in FIG. 1.

FIG. 3 is a diagram showing the relation between a plasma density and an oxide film thickness in utilizing a microwave plasma processing apparatus shown in FIG. 1.

FIGS. 4A, 4B and 4C are a schematic cross-sectional view illustrating a process for forming an insulating film utilizing a microwave plasma processing apparatus shown in FIG. 1.

FIG. 5 is a schematic cross-sectional view of a plasma processing apparatus according to a second embodiment of the present invention.

FIG. 6 is a schematic cross-sectional view of a plasma processing apparatus according to a third embodiment of the present invention.

FIG. 7 is a schematic cross-sectional view of a plasma processing apparatus according to a fifth embodiment of the present invention.

FIG. 8 is a schematic cross-sectional view of a plasma processing apparatus according to a sixth embodiment of the present invention.

FIG. 9 is a schematic cross-sectional view showing specific Application Example 1 of a plasma processing apparatus according to a first embodiment.

FIG. 10 is a schematic cross-sectional view showing specific Application Example 2 of a plasma processing apparatus according to a second embodiment.

### DETAILED DESCRIPTION OF THE PREFERRED EMBODIMENTS

Certain preferred embodiments of the invention will be described in detail below with reference to the drawings.

### First Embodiment

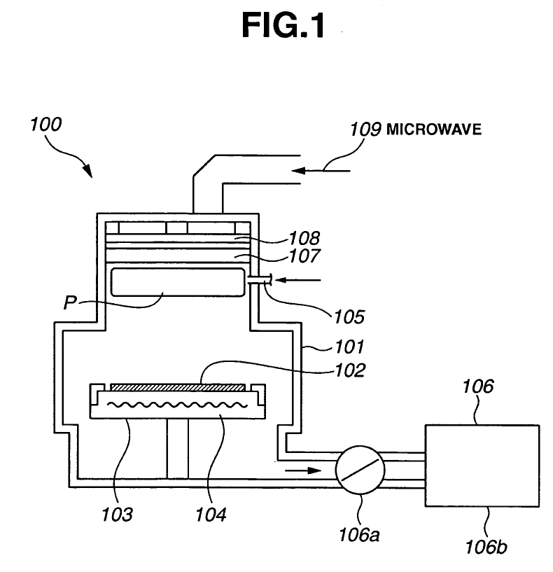

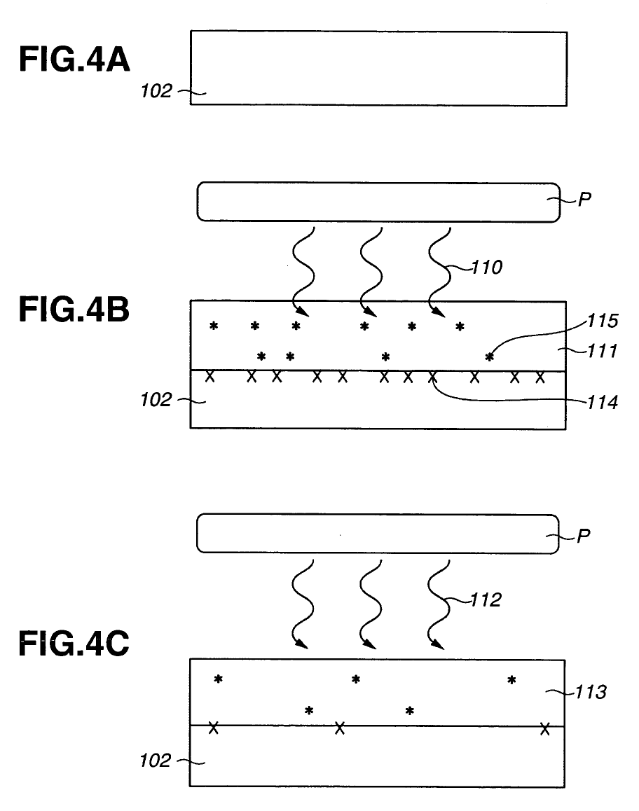

A plasma processing apparatus (hereinafter simply referred to as “processing apparatus”) 100 according to a first embodiment of the present invention will be described in detail with reference to FIGS. 1, 4A, 4B and 4C. In this embodiment, FIG. 1 is a schematic cross sectional view showing the processing apparatus 100. In FIG. 1, the processing apparatus 100 is connected to a microwave generating source or a high-frequency source (not shown) and includes a vacuum chamber (or a plasma processing chamber) 101, a substrate to be processed 102, a support base (or a mount base) 103, a temperature adjustment section 104, a gas introduction section 105, a pressure adjustment mechanism 106, a dielectric window or a high-frequency transmission section 107, and a microwave supply section or a high-frequency power supply section 108; and performs plasma processing to the substrate to be processed 102.

The microwave generating source includes, for example, a magnetron, and generates, for example, a microwave 109 of 2.45 GHz. In this embodiment, a microwave frequency can be selected from a range of 0.8 GHz to 20 GHz as deemed appropriate. Then, the microwave 109 is converted into a TM mode, a TE mode or the like, and is propagated through a waveguide. In a wave-guide path of the microwave 109 is provided an isolator, an impedance matching device and others. The isolator prevents a reflected microwave from returning to the microwave generating source, and absorbs such a reflected wave. The impedance matching device is provided with a power meter for detecting each intensity and phase of a traveling wave supplied from the microwave generating source to a load side, and a wave reflected by the load which returns to the microwave generating source. The matching device performs a function of matching the microwave generating source with its load side and is constituted of a 4E tuner, an EH tuner, a stub tuner and other tuners.

The plasma processing chamber 101 is a vacuum chamber which accommodates the substrate to be processed 102, and performs plasma processing on the substrate 102 under vacuum or reduced pressure. Note that in FIG. 1, a gate valve or the like for passing the substrate to be processed 102 between a load lock chamber (not shown) and the plasma processing chamber 101 is eliminated.

The substrate to be processed 102 is mounted on the support base 103. The support base 103 is accommodated in the plasma processing chamber 101, and supports the substrate to be processed 102.

The temperature adjustment section 104 employs a heater and the like. The temperature thereof is, for example, 600° C. or lower, and is controlled at a temperature suitable for processing, for example, 200° C. or higher and 400° C. or lower. The temperature adjustment section 104 includes, for example, a thermometer measuring the temperature of the support base 103, and a control section, for example, for controlling amperage from a power source to a heater wire (not shown) such that the temperature measured by the thermometer reaches a predetermined value.

The gas introduction section 105 is provided on the upper part of the plasma processing chamber 101 to supply a plasma processing gas to the plasma processing chamber 101. The gas introduction section 105 constitutes a part of a gas supply section. The gas supply section contains a gas supply source, a valve, a mass flow controller and a gas introduction pipe which connects those members. The gas supply section supplies a processing gas and a discharge gas for forming predetermined plasma P excited by the microwave 109. To swiftly ignite plasma, a rare or inert gas such as xenon, argon, helium or the like may be added at least at the time of ignition. The rare gas is not reactive, therefore does not adversely affect the substrate to be processed 102. The rare gas is also preferably easily ionized. Thus, a plasma ignition speed, when the microwave is introduced, can be increased. Further, the gas introduction section 105 may be separated, for example, into a processing gas introduction section and an inert gas introduction section, and these introduction sections may be arranged at separate positions.

An oxidizing gas for oxidizing the surface of the substrate to be processed 102 includes oxygen, ozone, water vapor, hydrogen peroxide, nitrogen monoxide, dinitrogen monoxide, nitrous oxide and others. As described above, these processing gases may be composed of a mixed gas comprising an oxidizing gas diluted by or admixed with at least one of helium, neon, argon, krypton, xenon, nitrogen or hydrogen as well as mixtures thereof.

The pressure adjustment mechanism 106 is provided in the lower part or the bottom part of the plasma processing chamber 101, and is constituted of a pressure regulating valve 106a, a pressure gage (not shown), a vacuum pump 106b and the control section (not shown). The control section (not shown), while operating the vacuum pump 106b, adjusts the pressure of the plasma processing chamber 101 by controlling the pressure regulating valve 106a (e.g., gate valve with pressure regulating function manufactured by VAT Vacuum Valves AG, and exhaust throttle valve manufactured by MKS Instruments, Inc.) which regulates in accordance with the opening of a valve such that a pressure gage detecting the pressure of the plasma processing chamber 101 reaches a predetermined value. As a result, via the pressure adjustment mechanism 106, the internal pressure of the plasma processing chamber 101 is controlled to be suitable for the processing.

The pressure at which an ionic oxidation reaction is suitably carried out is preferably in a range of 13 mPa to 150 Pa, and, more preferably, in a range of 665 mPa to 133.3 Pa. The vacuum pump 106b is constituted of, for example, a turbo-molecular pump (TMP), and is connected to the plasma processing chamber 101 via a pressure regulating valve (not shown) such as a conductance valve or the like.

The dielectric window 107 not only transmits the microwave 109 supplied from the microwave generating source to the plasma processing chamber 101, but also functions as a partition wall of the plasma processing chamber 101.

As shown in FIG. 1 power supply section 108 is preferably a slotted planar microwave supply section which includes a function of introducing microwaves 109 into the plasma processing chamber 101 via the dielectric window 107. A slotted endless circular waveguide or a multi-slot antenna of a coaxial introduction plate type if capable of supplying microwaves 109 in a plane is useful. The material of the planar microwave supply section 108 used for the microwave plasma processing apparatus 100 of the present invention is preferably conductive. To reduce the propagation loss of the microwave 109 as much as possible, Al, Cu, Ag/Cu plated SUS or the like having high conductivity is most suitable.

For example, in a case where the slotted planar microwave supply section 108 is a slotted endless circular waveguide, a cooling water channel and a slot antenna are provided. The slot antenna forms by interference a surface standing-wave on the vacuum side of the surface of the dielectric window 107. The slot antenna is a metallic circular plate having four pairs of, for example, a slot in a radius direction, a slot along a circumference direction, a large number of slots disposed in a concentric circle having a roughly T shape or in a spiral, or a pair of slots having a V shape. Note that, to perform the processing without dispersion and with uniformity across the entire area in the plane of the substrate to be processed 102, it is important that active species having excellent in-plane uniformity are supplied on the substrate to be processed 102. In the slot antenna, at least one slot or more are disposed, thus the plasma can be generated across a large area, and the control of plasma intensity and uniformity becomes easy.

Hereafter, the operation for forming an oxide film (insulating film) by the processing apparatus 100 will be described. First, a surface of a substrate to be processed 102 is cleaned by a well-known RCA cleaning method and a dilute fluoric acid cleaning method, and the cleaned substrate 102 is mounted on the base 103. Next, the inside of the plasma processing chamber 101 is exhausted via the pressure adjustment mechanism 106. Subsequently, the valve of the gas supply section (not shown) is opened, and the processing gas is introduced at a predetermined flow rate from the gas introduction section 105 to the plasma processing chamber 101 via the mass flow controller. Next, the pressure regulating valve 106a is controlled to hold the inside of the plasma processing chamber 101 at a predetermined pressure. Further, the microwave 109 is supplied from the microwave generating source to the plasma processing chamber 101 via the microwave supply section 108 and the dielectric window 107, and a plasma is generated in the plasma processing chamber 101. The microwave introduced into the microwave supply section 108 is propagated with a guide wavelength longer than free space, and is introduced from the slot into the plasma processing chamber 101 via the dielectric window 107, and propagated on the surface of the dielectric window 107 as a surface wave. The surface waves interfere with each other between adjacent slots to form a surface standing-wave. The electric field of this surface standing-wave generates a high density plasma. Since an electron density in a plasma generation region is at a high level, the processing gas can efficiently be dissociated. The active species such as ions, neutral radicals or the like in the plasma are transported to the vicinity of the substrate to be processed 102 by diffusion and other mechanisms, and arrive at the surface of the substrate which is to be processed 102.

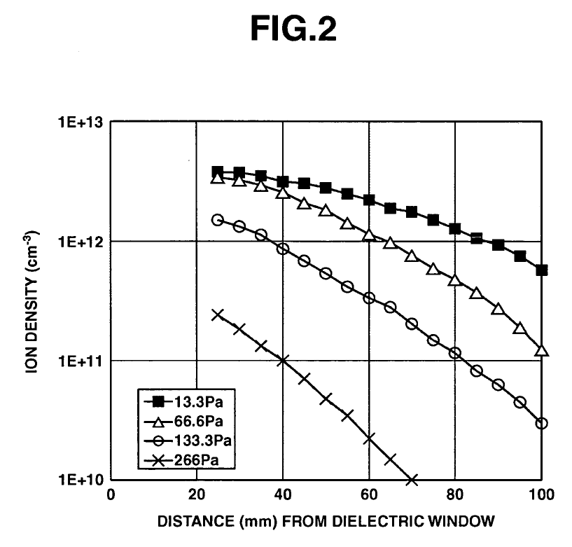

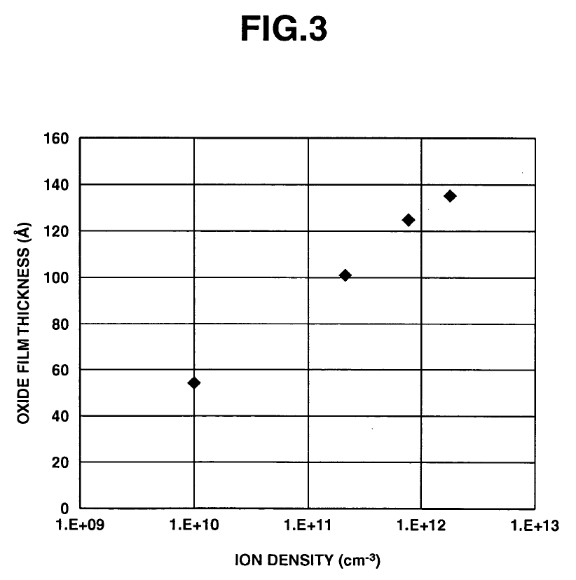

In the present invention, after ionic oxidation processing is performed, the pressure in the reaction vessel is changed, and neutral radical processing is performed. Therefore, in the same processing apparatus 101, both ionic oxidation processing and neutral radical processing are performed. This feature will be described with reference to FIG. 2, FIG. 3 and FIGS. 4A, 4B and 4C. In this embodiment, FIG. 2 illustrates the dependence on internal pressure of the ion density present in the plasma generated by a surface-wave interfered plasma source. FIG. 3 shows, for example, the relation between the ion density in the vicinity of the substrate to be processed and oxide film thickness. FIGS. 4A, 4B and 4C are schematic cross-sectional views for illustrating the formation of the insulating film.

In surface-wave plasma, the plasma is generated in a location extremely close to the dielectric window which is a microwave introduction section. From there the plasma is transported to the substrate to be processed by diffusion to process the substrate. When gas pressure becomes 250 Pa or higher, the ions in the plasma, as shown in FIG. 2, are rapidly reduced to extinction due to both factors of recombination with electrons and raising of diffusion coefficient as the ions are farther from a plasma generating section. On the other hand, when the gas pressure becomes 150 Pa or lower, a reduction in ion density becomes less pronounced, even if the substrate is spaced apart from the dielectric window 30 to 80 millimeters, and, consequently, a large amount of ions are implanted onto the substrate to be processed.

On the other hand, the relation between ion density in the vicinity of the substrate and oxide film thickness, as shown in FIG. 3, shows a tendency that as the ion density becomes greater, the oxide film formed for the same time duration becomes thicker. Therefore, when the substrate is oxidized at high speed, then, as the oxidation is carried out at high ion density, a desired film thickness can be formed in a shorter time.

Next, the correction of defects in the insulating film formed by the ion enriched plasma will be described. FIGS. 4A-4C show how defects in the oxide film can be reduced. FIG. 4A is a schematic cross-sectional view showing the substrate to be processed 102 after cleaning is completed. FIG. 4B is a schematic cross-sectional view showing the substrate to be processed 102 after the ionic oxidation processing is performed. FIG. 4C is a schematic cross-sectional view showing the substrate to be processed 102 after the neutral radical processing is performed.

First, to conduct ionic oxidation the inside of the processing chamber 101 is controlled to be at a predetermined pressure of 150 Pa or lower, and more preferably 100 Pa or lower. Subsequently, the microwave 109 is introduced from the microwave supply section 108 via the dielectric window 107 to generate the plasma P. The ion density in the plasma is reduced at a position farther from the plasma generating source. However, as described above, when a pressure is 150 Pa or lower, the ions generated at the plasma source are transported to the surface of the substrate to be processed 102, while roughly maintaining the ion density generated at the plasma source. The substrate to be processed 102 is exposed to the ionic oxygen plasma 110 generated at this stage to form a silicon oxide film 111 on the substrate to be processed 102 at a high speed, as shown in FIG. 4B. At this time, the silicon oxide film 111 contains many defects such as a defect 114 which generates an interface state by the impact of the ions, and a defect which has a possibility of significantly degrading electrical characteristics like a space-fixed charge 115.

Next, the inside of the processing chamber 101 is controlled to be at a predetermined pressure of 250 Pa or higher, and more preferably 350 Pa or higher. Subsequently, the microwave 109 is introduced from the microwave supply section 108 via the dielectric window 107 to generate the plasma P. As described above, at a pressure of 250 Pa or higher, the ions generated at the plasma source are rapidly reduced in density and are hardly transported to the surface of the substrate to be processed 102. Accordingly, only the neutral radicals having a longer life than the ions arrive at the substrate surface. The substrate to be processed 102 is exposed to the neutral radicals, thereby terminating and correcting defects present in the silicon oxide film 111. As shown in FIG. 4C, the silicon oxide film on the substrate to be processed 102 is thereby transformed into a low defect density silicon oxide film 113.

As described above, in the first embodiment, a bond between a silicon atom and an oxygen atom of the silicon oxide film 111 formed on the substrate to be processed 102 is cleaved by the impact of the ions having a high speed. The cleaved bond remains present as a dangling bond, hence the electrical characteristics are significantly degraded. However, in the neutral radical processing step which is performed after an ionic oxidation processing step, the neutral oxygen radicals cause less damage to the substrate. Further, the neutral radicals have a high reactivity and not only planarize a silicon interface at an atomic level, but also terminate the dangling bonds present in the film. Thus, by employing a neutral radical species after the ionic species, the resulting insulating film has a low interface state, a small fixed charge and a high quality.

In the above embodiment, the process gas for performing the ionic oxidation processing was the same as the process gas for subsequently performing the neutral radical processing. However, different process gases may also be utilized. In such a case, it is preferable that, after the ionic oxidation processing is completed, the introduction of the first process gas is terminated. Then, after the plasma processing chamber is sufficiently exhausted from an exhaust section, a second reaction gas for the next oxidation processing is introduced. After the chamber is adjusted to a predetermined pressure, the neutral radical processing is then started.

### Second Embodiment

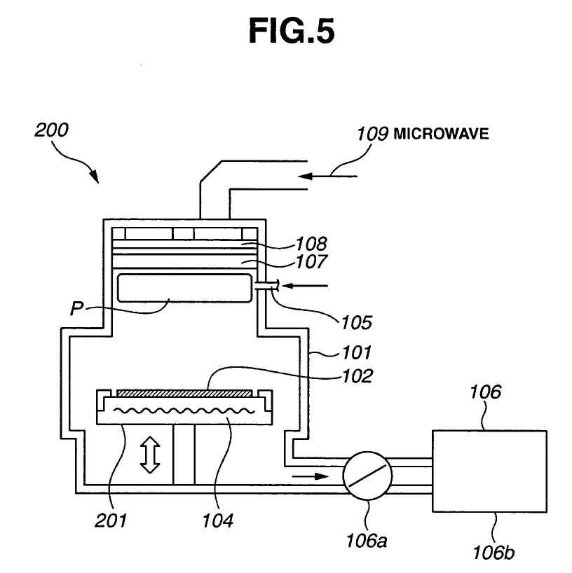

A processing apparatus 200 according to a second embodiment of the present invention will be described in detail with reference to FIG. 5. FIG. 5 is a schematic cross-sectional view showing the processing apparatus 200, and includes a surface-wave interfered plasma source. Note that the constitution of a microwave 109 supply section, a gas supply section, a pressure adjustment section or the like is the same as in the first embodiment.

The substrate to be processed 102 is mounted on a support base 201 capable of being moved nearer or farther from a plasma source. The support base 201 is controlled to be at an interval suitable for processing from a plasma generating section, for example, at an interval of 20 mm or wider and 200 mm or narrower.

An ion density present in plasma, as shown in FIG. 2, is rapidly reduced under a specific pressure condition as the substrate is moved away from the plasma generating section. Therefore, the interval between the plasma generating section and the substrate to be processed is changed by moving the support base 201 so that a flux of ions incident on the substrate to be processed can be controlled. Further, two different types of processing, namely ionic oxidation processing and neutral radical processing can optionally be performed.

The operation for forming an oxide film by the processing apparatus 200 will be described below. First, a surface is cleaned by a well-known RCA cleaning method and a dilute fluoric acid cleaning method. The cleaned substrate to be processed 102 is mounted on the support base 201, and the position of the support base 201 is adjusted to be at a predetermined position where the desired concentration of ions arrives at the surface of the substrate to be processed 102. Next, the inside of the plasma processing chamber 101 is exhausted via the pressure adjustment mechanism 106. Subsequently, the valve of the gas supply section (not shown) is opened, and a processing gas is introduced at a predetermined flow rate from the gas introduction section 105 to the plasma processing chamber 101 via a mass flow controller. Next, the pressure regulating valve 106a is controlled to hold the inside of the plasma processing chamber 101 at a predetermined pressure.

Further, the microwave 109 is supplied from the microwave generating source to the plasma processing chamber 101 via the microwave supply section 108 and the dielectric window 107, and the plasma P is generated in the plasma processing chamber 101. The microwave introduced into the microwave supply section 108 is propagated with a guide wavelength longer than free space and is introduced from a slot into the plasma processing chamber 101 via the dielectric window 107. The microwaves are propagated on the surface of the dielectric window 107 as a surface wave. The surface waves interfere with each other between adjacent slots to form a surface standing-wave.

High density plasma P is generated by the electric field of this surface standing-wave. Active species such as the ions, neutral radicals or the like in the plasma are transported to the vicinity of the substrate to be processed 102 by diffusion and arrive at the surface of the substrate to be processed 102. The surface of the substrate to be processed 102 is oxidized by the ions at a high speed to form the silicon oxide film 111.

Next, the support base 201 is moved sufficiently farther from the plasma source than the above-mounted position, such that extinction of the ions in the plasma occurs to reduce ion concentration significantly. At the substrate to be processed 102 only the neutral radicals, having a longer life than the ions, arrive, thereby correcting defects occurring in the silicon oxide film 111 by ionic oxidation processing, thus modifying the film to a low defect density silicon oxide film 113.

In the second embodiment, the silicon oxide film 113 formed on the substrate to be processed 102 is, as in the first embodiment, a silicon oxide film having an extremely low defect density therein and is of high quality. In the second embodiment, when the ionic oxidation processing step and the neutral radical processing step are performed by adjusting the position of the support base 201 (rather than the pressure) and the pressure in a vacuum chamber is preferably maintained as a constant, the constant pressure is preferably at a value from 100 mPa to 700 Pa, and more preferably from 10 Pa to 150 Pa.

In the second embodiment, the process gas for performing the ionic oxidation processing is preferably the same as the process gas used subsequently in the neutral radical processing. However, different process gases may be utilized. In such a case, it is preferable that, after the ionic oxidation processing is completed, the introduction of the first process gas is terminated and the plasma processing chamber is sufficiently exhausted from an exhaust section. A second reaction gas for the next oxidation processing is introduced, and, after being adjusted at a predetermined pressure, the neutral radical processing is started.

### Third Embodiment

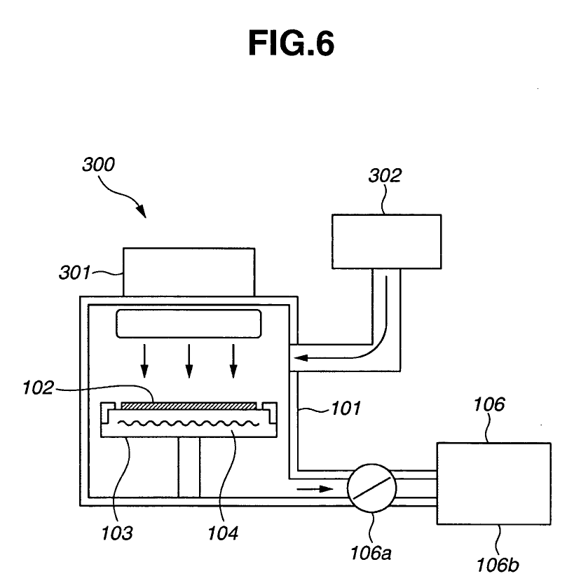

A processing apparatus 300 according to a third embodiment of the present invention will be described in detail with reference to FIG. 6. FIG. 6 is a schematic cross-sectional view showing the processing apparatus 300.

The processing apparatus 300 includes a high density plasma source 301, a remote plasma source 302, the vacuum chamber (or the plasma processing chamber) 101, the substrate to be processed 102, the support base (or the mount base) 103, the temperature adjustment section 104 and the pressure adjustment mechanism 106, and performs plasma processing to the substrate to be processed 102.

The processing apparatus 300 is provided with two plasma sources, that is, the plasma source 301 for performing the ionic oxidation processing and the remote plasma source 302 for supplying only neutral radicals for performing neutral radical processing to the processing chamber 101, and each of which can independently generate plasma.

Hereafter, the operation for forming an oxide film by a processing apparatus 300 will be described. First, a surface is cleaned by a well-known RCA cleaning method and a dilute fluoric acid cleaning method. A cleaned substrate to be processed 102 is then mounted on the support base 103. Next, the inside of the plasma processing chamber 101 is exhausted via the pressure adjustment mechanism 106. Subsequently, a plasma is generated by a first plasma source 301 for generating ionic oxidizing species, and the substrate to be processed 102 is exposed to the plasma to form the silicon oxide film 111 at a high speed. After the silicon oxide film 111 having a desired film thickness is formed, plasma supply by the plasma source 301 is terminated. Subsequently, a plasma is generated by the second plasma source 302 for performing the neutral radical processing, and the substrate to be processed 102 is exposed to only the neutral radicals, thereby correcting defects arising in the silicon oxide film 111 during the ionic oxidation processing, and modifying the film to the low defect density silicon oxide film 113.

In the third embodiment, with respect to the plasma source 301 for performing the ionic oxidation processing and the plasma source 302 for performing the neutral radical processing, any plasma excitation means such as CCP (capacitively coupled plasma), ICP (Inductively Coupled Plasma), a helicon wave, an ECR (electron cyclotron resonance), a microwave, a surface-wave or the like are applicable.

In the above embodiment, when the ionic oxidation processing is performed, the plasma is not supplied from the plasma source for performing the neutral radical processing. However, the plasma may be generated in both plasma sources at the same time.

### Fourth Embodiment

In a processing apparatus according to a fourth embodiment of the present invention, high-frequency power is varied during generating plasma to control an ion density in the plasma, thus a flux of ions arriving at the substrate to be processed 102 is controlled. The processing apparatus can also be applied to any processing apparatus shown in the above embodiments.

Referring to the processing apparatus 100 as an example, the operation for forming an oxide film will be described. First, a surface is cleaned by a well-known RCA cleaning method and a dilute fluoric acid cleaning method, and a cleaned substrate to be processed 102 is mounted on the base 103. Next, the inside of the plasma processing chamber 101 is exhausted via the pressure adjustment mechanism 106. Subsequently, the valve of a gas supply section (not shown) is opened, and a processing gas is introduced at a predetermined flow rate from the gas introduction section 105 to the plasma processing chamber 101 via a mass flow controller. Next, the pressure regulating valve 106a is regulated, and the inside of the plasma processing chamber 101 is held at a predetermined pressure. Further, a predetermined electric power, for example 1.5 to 3 kW is turned on for a microwave generating source or a high-frequency source (not shown). The electric power is capable of generating high density ions, and a microwave is generated. This microwave is supplied to the plasma processing chamber 101 via the microwave supply section 108 and the dielectric window 107, and high density plasma P is generated in the plasma processing chamber 101.

The surface of the substrate to be processed 102 is exposed to the high density plasma to form the silicon oxide film 111 at a high speed. After the silicon oxide film 111 having a desired film thickness is formed, electric power which is lower than that when the high density plasma is generated, for example, 0.5 to 1 kW, is supplied to the microwave generating source or the high-frequency source, and the plasma having a lower density than the above plasma is generated. The surface of the substrate to be processed 102 is exposed to the low density plasma to enable neutral radical processing with low ion content, thus modifying the silicon oxide film 111 to the low defect density silicon oxide film 113.

In the fourth embodiment, an ionic oxidation reaction and modification processing by neutral radicals are controlled by increase or decrease of high-frequency power during the generation of the plasma. However, if necessary, a processing pressure and a substrate position are controlled as in the first and second embodiments, thus an ion amount implanted in the substrate to be processed may be further controlled.

### Fifth Embodiment

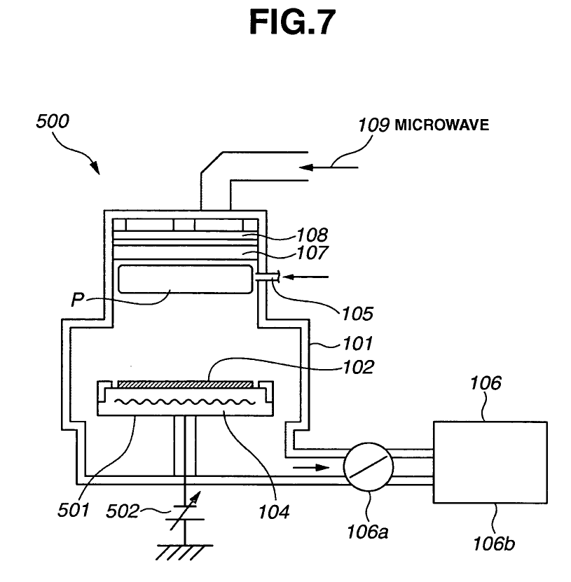

A processing apparatus 500 according to a fifth embodiment of the present invention will be described in detail with reference to FIG. 7. FIG. 7 is a schematic cross-sectional view showing the processing apparatus 500, and the processing apparatus 500 includes a surface-wave interfered plasma source. Note that the constitution of a microwave supply section, a gas supply section, a pressure adjustment section or the like is the same as the first embodiment.

The substrate to be processed 102 is mounted on a support base 501 where a bias potential can optionally be applied to the substrate to be processed 102 by a bias voltage application section 502.

The operation for forming an oxide film by the processing apparatus 500 will be described. First, a surface is cleaned by a well-known RCA cleaning method and a dilute fluoric acid cleaning method, and a cleaned substrate to be processed 102 is mounted on the base 501. Next, the inside of the plasma processing chamber 101 is exhausted via the pressure adjustment mechanism 106. Subsequently, the valve of the gas supply section (not shown) is opened, and a processing gas is introduced at a predetermined flow rate from the gas introduction section 105 to the plasma processing chamber 101 via a mass flow controller. Next, the pressure regulating valve 106a is regulated, and the inside of the plasma processing chamber 101 is held at a predetermined pressure.

After a predetermined bias potential is provided to the support base 501, the microwave 109 is supplied from the microwave supply source to the plasma processing chamber 101 via the microwave supply section 108 and the dielectric window 107, and plasma P is generated in the plasma processing chamber 101. The substrate to be processed 102 is exposed the to the plasma to form the silicon oxide film 111. The bias potential applied to the substrate to be processed 102 provides energy to ions which are implanted on the substrate to be processed 102 at an accelerated speed, and also increases a rate of oxidation due to a potential gradient in a film. After the silicon oxide film 111 having a desired film thickness is formed, a bias voltage applied to the support base 104 is turned off, and an ion implantation having high energy is terminated. Subsequently, the substrate to be processed 102 is exposed to neutral radicals in the plasma, thereby correcting a defect arising in the silicon oxide film 111 while the ionic oxidation processing is performed, and modifying the film to the low defect density silicon oxide film 113.

In the fifth embodiment, an ionic oxidation reaction and modification processing by the neutral radicals are controlled by on/off of the bias voltage. However, if necessary, a processing pressure and a substrate position are also controlled as described above, thus an amount of ions implanted in the substrate to be processed 102 may be controlled.

### Sixth Embodiment

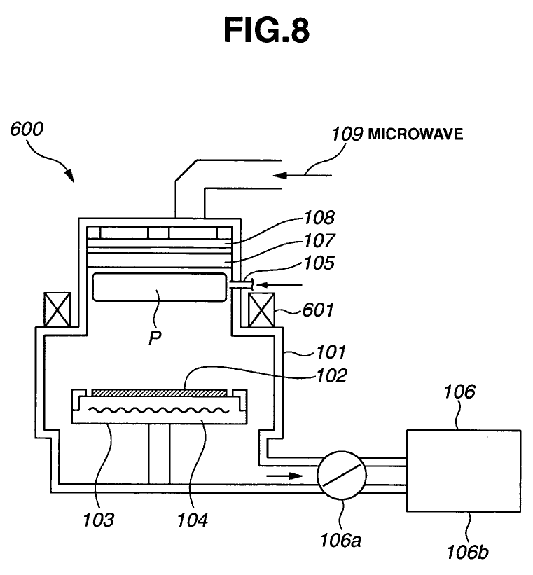

A processing apparatus 600 according to a sixth embodiment of the present invention will be described in detail with reference to FIG. 8. FIG. 8 is a schematic cross-sectional view showing the processing apparatus 600, and the processing apparatus 600 includes a surface-wave interfered plasma source.

Note that the constitution of a microwave supply section, a gas supply section, a pressure adjustment section or the like is the same as the first embodiment. Reference numeral 601 denotes a magnetic field generating section, and any magnetic field configuration is applicable as long as the magnetic field is perpendicular to an electric field generated in a width direction of slots.

The operation for forming an oxide film by the processing apparatus 600 will be described. First, a surface is cleaned by a well-known RCA cleaning method and a dilute fluoric acid cleaning method, and a cleaned substrate to be processed 102 is mounted on the support base 103. Next, the inside of the plasma processing chamber 101 is exhausted via the pressure adjustment mechanism 106. Subsequently, the valve of the gas supply section (not shown) is opened, and the processing gas is introduced at a predetermined flow rate from the gas introduction section 105 to the plasma processing chamber 101 via a mass flow controller. Next, the pressure regulating valve 106a is regulated, and the inside of the plasma processing chamber 101 is held at a predetermined pressure.

After a predetermined magnetic field is formed by a magnetic field generating section 601 such as an electromagnet or the like, a microwave is supplied from a microwave supply source to the plasma processing chamber 101 via the microwave supply section 108 and the dielectric window 107, and plasma P is generated in the plasma processing chamber 101. Electrons in the plasma are accelerated by a microwave electric field, are trapped by a superimposed magnetic field, and stimulate the dissociation of the plasma to form high density plasma, a so-called magnetron plasma. The substrate to be processed 102 is exposed to the high density plasma to form the silicon oxide film 111 at a high speed. After the silicon oxide film 111 having a desired film thickness is formed, the generation of the superimposed magnetic field is terminated, and the plasma having a lower density than the substrate to be processed 102 is exposed to the above plasma, thereby correcting defects arising in the silicon oxide film 111 while the ionic oxidation processing is performed, and modifying the film to the low defect density silicon oxide film 113.

In the sixth embodiment, an ionic oxidation reaction and modification processing by neutral radicals are controlled by the presence or absence of the magnetic field generated by the magnetic field generating section. However, if necessary, a processing pressure and a substrate position are controlled, thus an ion implanted amount to the substrate to be processed may be controlled. Other embodiments disclosed herein may also be used in any suitable combination with the sixth embodiment to exert additional control over defects. Similarly, any embodiment disclosed may be used in suitable combination with any other embodiment or embodiments.

### Seventh Embodiment

A plasma processing apparatus in a seventh embodiment of the present invention is similar to the first embodiment.

The operation for forming an oxide film will be described. First, a surface is cleaned by a well-known RCA cleaning method and a dilute fluoric acid cleaning method, and a cleaned substrate to be processed 102 is mounted on the support base 103. Next, the inside of the plasma processing chamber 101 is exhausted via the pressure adjustment mechanism 106. Subsequently, the valve of a gas supply section (not shown) is opened, and a processing gas is introduced at a predetermined flow rate from the gas introduction section 105 to the plasma processing chamber 101 via a mass flow controller. In this embodiment, a first processing gas which can be utilized is a gas as oxygen, ozone, water vapor, hydrogen peroxide, or mixtures thereof, or a mixed gas in which the primary gas thereof is diluted by or mixed with at least one of helium, neon, argon, krypton, xenon, nitrogen, or hydrogen. Next, the pressure regulating valve 106a is regulated, and the inside of the plasma processing chamber 101 is held at a predetermined pressure. Subsequently, a microwave is supplied from a microwave supply source to the plasma processing chamber 101 via the microwave supply section 108 and the dielectric window 107, and plasma P is generated in the plasma processing chamber 101. The substrate to be processed 102 is exposed to the plasma to form the silicon oxide film 111.

After the silicon oxide film 111 having a desired film thickness is formed, plasma discharge and gas supply are terminated, and the inside of the plasma processing chamber 101 is exhausted by the pressure adjustment mechanism 106. Subsequently, the valve of the gas supply section (not shown) is opened, and a second processing gas is introduced at a predetermined flow rate from the gas introduction section 105 to the plasma processing chamber 101 via a mass flow controller. In this embodiment, hydrogen is utilized as the processing gas. Subsequently, the microwave 109 is supplied from a microwave generating source to the plasma processing chamber 101 via the microwave supply section 108 and the dielectric window 107, and plasma P is generated in the plasma processing chamber 101.

Ions generated in the plasma processing using hydrogen processing gas cause only small damage to a film, since hydrogen is the lightest element. Further, a hydrogen radical is formed having high reactivity which terminates and corrects any defects in the film. The substrate to be processed 102 is exposed to the hydrogen plasma, thereby modifying the silicon oxide film 111 to the low defect density silicon oxide film 113.

In the seventh embodiment, surface-wave interfered plasma is used as the plasma source, and any plasma excitation means such as CCP, ICP, a helicon wave, an ECR, a microwave, a surface-wave or the like is also applicable thereto. The sources may be the same plasma sources or different plasma sources.

The oxide film formed as above described is favorably utilized as a gate insulating film of a MISFET (Metal Insulator Semiconductor Field Effect Transistor), a floating-gate oxide film of a flash memory device, and a control-gate oxide film.

A specific example of the plasma processing apparatus and method will be described below. However, the present invention is not limited to these examples.

### EXAMPLE 1

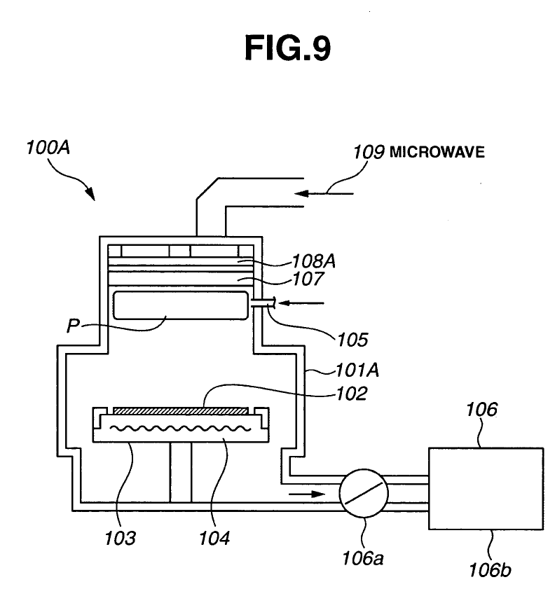

As one example of the processing apparatus 100, a microwave plasma processing apparatus 100A shown in FIG. 9 was chosen, and a gate insulating film of a semiconductor device was formed therewith. The processing apparatus 100A can excite surface-wave interfered plasma by a microwave. Reference numeral 108A denotes a slotted endless circular waveguide through which the microwave is introduced to a plasma processing chamber 101A via the dielectric window 107. Note that, in FIG. 9, the same unit has the same numerals as in FIG. 1, but with respect to modifications made to a corresponding unit, a letter is added to the same reference numeral.

In the above case, the slotted endless circular waveguide 108A in a TE10 mode was used in which a cross-section of an inner wall has a dimension of 27 mm×96 mm (a guide wavelength is 158.8 mm) and a central diameter of a waveguide of 151.6 mm (a peripheral length is three times the length of the guide wavelength). The slotted endless circular waveguide 108A is made entirely of aluminum alloy to prevent a propagation loss of the microwave. A slot for introducing the microwave to the plasma processing chamber 101A is formed on the H face of the slotted endless circular waveguide 108A. The slot is a rectangle 40 mm long and 4 mm wide, and the six slots are radially formed at a position having a center diameter of 151.6 mm and at intervals of 60°. A 4E tuner, a directional coupler, an isolator, and a microwave source (not shown) with a frequency of 2.45 GHz are connected, in turn, to the slotted endless circular waveguide 108A.

An 8-inch p-type single crystal silicon (orientation of planes-100, resistivity-10 Ωcm) was used as the substrate to be processed 102. First, the substrate to be processed 102 was transported to the plasma processing chamber 101, and was mounted on the support base 103. Then, the substrate to be processed 102 was heated and kept at 300° C. by the heater in the temperature adjustment section 104.

Next, an oxygen gas and a helium gas were introduced into the processing chamber 101 at a flow rate of 50 sccm and 450 sccm, respectively, and the opening of the pressure regulating valve 106a provided in the pressure adjustment mechanism 106 was regulated to keep the pressure in the processing chamber 101 at 66.6 Pa. Thereafter, microwave power of 2.45 GHz and 1.5 kW was supplied into the processing chamber 101 via a microwave supply section 108A and the dielectric window 107 to generate plasma P. The substrate to be processed 102 was exposed to the generated oxygen plasma for 3 minutes to form a silicon oxide film. The thickness of the silicon oxide film formed at this time was measured by an ellipsometer and found to have a thickness of 8.1 nm.

Next, after the inside of the processing chamber 101 was sufficiently exhausted to a vacuum of 10⁻³ Pa by a vacuum pump, the oxygen gas was introduced at a flow rate of 500 sccm and the opening of the pressure regulating valve 106a was regulated to keep the pressure in the processing chamber 101 at 400 Pa. Thereafter, a microwave power of 2.45 GHz and 1.5 kW was supplied into the processing chamber 101 via the microwave supply section 108 and the dielectric window 107 to generate the plasma P. The silicon oxide film was exposed to generated oxygen plasma for 1 minute, and the silicon oxide film was modified by neutral radicals. The thickness of the silicon oxide film after being so modified was measured by the ellipsometer and was found to have thickness of 8.1 nm. Hardly any fluctuation in film thickness after being modified was observed.

Next, a capacitor having MOS structure was produced using a silicon oxide film formed by the above processing method and a silicon oxide film oxidized only in an ionic oxidation step of the above processing method and its current-voltage characteristic was evaluated. As a result of this evaluation, it was confirmed that the oxide film which was subjected additionally to the neutral radical processing of the present invention was about one digit smaller in leakage current than the oxide film which was not subjected to the neutral radical processing. For example, the leakage current density through the oxide film which was subjected additionally to the neutral radical processing was 1.8E-4 A/cm² at an electric field strength of 10 MV/cm, while the leakage current density through the oxide film which was not subjected to the neutral radical processing was 9.7E-4 A/cm² at an electric field strength of 10 MV/cm.

Further, TDDB (Time Dependent Dielectric Breakdown) was measured and it was confirmed that, in a case where oxidation correction was performed, breakdown time becomes around one digit longer than the case where the oxidation was not corrected. For example, the time for 50% cumulative failures when a stress of 0.1 A/cm² was applied to the oxide film which was subjected additionally to the neutral radical processing was 6.8E2 sec, while the time for 50% cumulative failures when a stress of 0.1 A/cm² was applied to the oxide film which was not subjected to the neutral radical processing was 8.7E1 sec.

### EXAMPLE 2

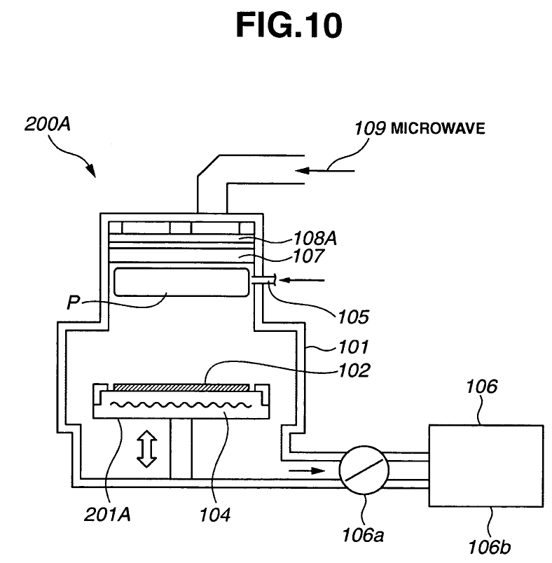

As one example of the processing apparatus 200, microwave plasma processing apparatus 200A shown in FIG. 10 was chosen, and a gate insulating film of a semiconductor device was formed therewith. The processing apparatus 200A can excite surface-wave interfered plasma by a microwave. Reference numeral 108A denotes a slotted endless circular waveguide through which the microwave is introduced to a plasma processing chamber 101A via the dielectric window 107. Further, reference numeral 201A denotes a stage which can move farther from and near to a plasma source. Note that, in FIG. 10, the same unit has the same reference numeral as in FIG. 1, and with respect to the modifications made, a letter is added to the corresponding numerical unit.

In the above case, the slotted endless circular waveguide 108A in a TE10 mode was used in which a cross-section of an inner wall has a dimension of 27 mm×96 mm (a guide wavelength is 158.8 mm) and a central diameter of a waveguide of 151.6 mm (a peripheral length is three times the length of the guide wavelength). The slotted endless circular waveguide 108A is entirely made of aluminum alloy to prevent a propagation loss of the microwave. A slot for introducing the microwave to the plasma processing chamber 101A is formed on the H face of the slotted endless circular waveguide 108A. The slot is a rectangle 40 mm long and 4 mm wide, and the six slots are radially formed at a position having a center diameter of 151.6 mm and at intervals of 60°. A 4E tuner, a directional coupler, an isolator, and a microwave source (not shown) with a frequency of 2.45 GHz are connected, in turn, to the slotted endless circular waveguide 108A.

An 8-inch p-type single crystal silicon (orientation of planes-100, resistivity-10 Ωcm) was used as the substrate to be processed 102. First, the substrate to be processed 102 was carried to the plasma processing chamber 101 and was mounted on a stage 201A, and the stage was moved 70 mm apart from the dielectric window 107. Then, the substrate to be processed 102 was heated and kept at 300° C. by the heater 104.

Next, an oxygen gas and a helium gas were introduced into the processing chamber 101 at a flow rate of 50 sccm and 450 sccm respectively and the opening of the pressure regulating valve 106a provided in the pressure adjustment mechanism 106 was regulated to keep the pressure in the processing chamber 101 at 66.6 Pa. Thereafter, microwave power of 2.45 GHz and 1.5 kW was supplied into the processing chamber 101 via a microwave supply section 108A and the dielectric window 107 to generate the plasma P. The substrate to be processed 102 was exposed to the generated oxygen plasma for 3 minutes to form a silicon oxide film. The thickness of the silicon oxide film formed at this time was measured by an ellipsometer and found to have thickness of 8.1 nm.

Next, the substrate to be processed 102 was carried to the plasma processing chamber 101 and was mounted on the stage 201A, and the stage 201A was moved 150 mm apart from the dielectric window.

Next, after the inside of the processing chamber 101 was sufficiently exhausted to a vacuum of 10⁻³ Pa by a vacuum pump 106b, the oxygen gas and the helium gas were introduced at a flow rate of 50 sccm and 450 sccm respectively, and the opening of the pressure regulating valve 106a was regulated to keep the pressure in the processing chamber 101 at 66.6 Pa. Thereafter, microwave power of 2.45 GHz and 1.5 kW was supplied into the processing chamber 101 via the microwave supply section 108 and the dielectric window 107 to generate plasma P. The silicon oxide film was exposed to the generated oxygen plasma for 3 minutes, and the silicon oxide film was modified by neutral radicals. The thickness of the silicon oxide film after being modified was measured by the ellipsometer and was found to have thickness of 8.2 nm, and there was barely observed a fluctuation in film thickness.

Next, a capacitor having MOS structure was produced using (a) a silicon oxide film formed by the above processing method and (b) a silicon oxide film oxidized only in an ionic oxidation step and their current-voltage characteristics were evaluated. As a result of this evaluation, it was confirmed that the oxide film (a) which was subjected additionally to the neutral radical processing of the present invention was about one digit smaller in leakage current than the oxide film (b) which was not subjected to the neutral radical processing. For example, the leakage current density through the oxide film which was subjected additionally to the neutral radical processing was 1.8E-4 A/cm² at an electric field strength of 10 MV/cm, while the leakage current density through the oxide film which was not subjected to the neutral radical processing was 9.7E-4 A/cm² at an electric field strength of 10 MV/cm.

Further, TDDB was measured and it was confirmed that, in a case where oxidation correction was performed, a breakdown time becomes around one digit longer than the case where oxidation was not corrected. For example, the time for 50% cumulative failures when a stress of 0.1 A/cm² was applied to the oxide film which was subjected additionally to the neutral radical processing was 6.8E2 sec, while the time for 50% cumulative failures when a stress of 0.1 A/cm² was applied to the oxide film which was not subjected to the neutral radical processing was 8.7E1 sec.

### EXAMPLE 3

As one example of the processing apparatus according to the seventh embodiment, the processing apparatus 100A shown in FIG. 9 was chosen, and a gate insulating film of a semiconductor device was formed therewith.

An 8-inch p-type single crystal silicon (orientation of planes-100, resistivity-10 Ωcm) was used as the substrate to be processed 102. First, the substrate to be processed 102 was carried to the plasma processing chamber 101, was mounted on a movable base 103, and was controlled at a distance of 100 mm from the dielectric window 107. Then, the substrate to be processed 102 was heated and kept at 400° C. by the heater of the temperature adjustment section 104.

An oxygen gas and a helium gas were introduced into the plasma processing chamber 101 at a flow rate of 50 sccm and 450 sccm, respectively, and the opening of the pressure regulating valve 106a was regulated to keep the pressure in the processing chamber 101 at 133 Pa. Thereafter, microwave power of 2.45 GHz and 2 kW was supplied into the processing chamber 101 via a microwave supply section 108A and the dielectric window 107 to generate plasma P. The substrate to be processed 102 was exposed to the generated oxygen plasma for 15 minutes to form a silicon oxide film.

Next, after the inside of the processing chamber 101 was sufficiently exhausted to a vacuum of 10⁻³ Pa by a vacuum pump, a hydrogen gas was introduced at a flow rate of 500 sccm and the opening of the pressure regulating valve 106a was regulated to keep the pressure in the processing chamber 101 at 133 Pa. Thereafter, a microwave power of 2.45 GHz and 2 kW was supplied into the processing chamber 101 via the microwave supply section 108A and the dielectric window 107 to generate the plasma P. The silicon oxide film was exposed to the generated hydrogen plasma for 1 minute, and the silicon oxide film was modified.

A capacitor having MOS structure was produced using an insulating film formed by the above method and its electrical characteristic was evaluated. The evaluation indicated a favorable interface state density of about 9.8×10¹⁰ eV⁻¹ cm⁻².

As described above, according to each embodiment, the ionic oxidation processing is performed on a semiconductor substrate and the oxidation is corrected by the neutral radical, thus a silicon oxide film which has few defects with respect to an interface state and a fixed charge, and is of good quality, can be formed at a high speed. Therefore, a high performance MOS device can be obtained by utilizing the silicon oxide film thus formed.

As described above, according to each embodiment, in a first step of oxidation, which is carried out with ions, a significantly high speed oxidation processing can be performed. Further, in a second step of the oxidation, the amount of ions arriving at the substrate is controlled, and the oxidation is carried out by the neutral radical species. Accordingly, bonding defects or the like in the oxide film can be corrected. Such defects arise from the ion impact during oxidation in the first step. Further, hydrogen, having higher termination ability, can be used as the processing gas in the second step, and, thus, the oxide film can be further corrected.

According to the present invention, it becomes possible to provide a processing method and a processing apparatus which enables one to form an insulating film having high reliability at a high speed.

While the present invention has been described with reference to exemplary embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions. For example, if desired, any appropriate combination of the features of the first to seventh embodiments may be employed.

This application claims priority from Japanese Patent Application No. 2004-194233 filed Jun. 30, 2004, which is hereby incorporated by reference herein.

What is claimed is:

1. A method for forming an oxide film comprising:
a first step of oxidizing an article employing a plasma comprising oxidizing species including ions to form the oxide film having a desired film thickness; and
a second step of controlling an amount of the ions in the plasma at a surface of the article such that the article is processed by neutral radical species to reduce defects in the oxide film.

2. The method according to claim 1, wherein the first step is performed at a pressure of 150 Pa or lower, and the second step is performed at a pressure of 250 Pa or higher.

3. The method according to claim 1, wherein the desired film thickness is from 30 Å to 200 Å.

4. The method according to claim 1, wherein the first step is performed by locating the substrate to be processed at a distance from a plasma source sufficient to conduct ionic oxidation, and the second step is performed by locating the substrate to be processed farther from the plasma source than in the first step sufficient to conduct neutral radical processing.

5. The method according to claim 1, wherein the first step is performed by a first plasma source for generating ionic oxidizing species, and the second step is performed by terminating the supply of the plasma from the first plasma source and by employing a second plasma source supplying remote plasma.

6. The method according to claim 1, wherein, in the second step, plasma is excited at least with lower power than in the first step.

7. The method according to claim 1, wherein the first step is performed by applying a bias voltage to a support base on which a substrate to be processed is mounted, and the second step is performed by terminating the application of the bias voltage.

8. The method according to claim 1, wherein the first step is performed by generating a magnetic field by a magnetic field generating section in a plasma generating section, and the second step is performed by terminating the generation of the magnetic field.

9. The method according to claim 1, wherein, in the first step, (i) at least one of oxygen, ozone, water vapor, or hydrogen peroxide, or (ii) a mixed gas in which a gas is diluted with or admixed with at least one of helium, neon, argon, krypton, xenon, nitrogen, or hydrogen is employed as a processing gas.

10. The method according to claim 9, wherein, in the second step, hydrogen is employed as a processing gas.

11. The method according to claim 1, wherein the article to be oxidized which is exposed at a surface of the substrate is single crystal silicon, polycrystal silicon, amorphous silicon, silicon carbide, or silicon germanium.

12. The method according to claim 1, wherein a plasma source generating the plasma is a surface-wave plasma source.

13. The method according to claim 12, wherein the plasma source is a surface-wave interfered plasma source.

14. An apparatus for an oxide film comprising:
oxide film-forming means for oxidizing an article to be processed using oxidizing species including ions in a plasma to form the oxide film having a desired film thickness; and
neutral radical species processing means for controlling an amount of the ions in the plasma at a surface of the article such that the article is processed by neutral radical species.
